(19) United States
(12) Patent Application Publication
(10) Pub. No.: US 2011/0036617 A1
(43) Pub. Date: Feb. 17, 2011

(54) Compensating Conductive Circuit

(76) Inventor: Leonid Kokurin, Moscow (RU)

Correspondence Address: HOUSTON ELISEEVA, 420 BEDFORD ST, SUITE 155, LEXINGTON, MA, 02420, US

(21) Appl. No.: 11/833,617

(22) Filed: Aug. 3, 2007

(51) Int. Cl. H05K 1/00

(52) U.S. Cl. 174/250

(57) ABSTRACT

A audio, video, and digital signal compensating conductive circuit consisting of one or more main electric conductor(s) and one or more non-terminated compensating conductor(s) to enhance transmission performance of an electrical signal. One embodiment is an electric cable comprising a one or more of said compensating conductive circuits. Another embodiment is a Printed Circuit Board (PCB) that has a plurality of said electric wires embedded in the CB. Said compensating conductive circuit has at least one main electric conductor, having purpose of carrying electric current between the signal source and the load, and at least one non-terminated compensating electric conductor, one end of said non-terminated compensating electric conductor is connected to said main electric conductor, while the other end of said non-terminated compensating electric conductor is unconnected.

### FIELD OF INVENTION

The present invention relates to an electric wire suitable for transmitting an electrical current, e.g., an alternating current (AC) or direct current (DC), impulse or a communication signal such as a voice or data transmission signal. More particularly it relates to special electric wires forming a compensating conductive circuit that enable a reduction in signal distortions for impulse and alternating signals caused by skin effect in electrical conductors.

### BACKGROUND OF THE INVENTION

The understanding of the phenomena involved in the transmission of alternating signals through the electric wires and cables is a crucial ingredient of the present invention, and now will be described hereinafter in a brief and simplified form.

It is well known from the electromagnetic theory that in an ideal electric conductor with infinite conductivity, the electric current propagates to the surface of the conductor, as the electromagnetic field within the conductor is essentially zero. Since any real-world electric conductor is not ideal and has finite conductivity, a part of an external electromagnetic (EM) field, surrounding the conductor, propagates into the conductor through its surface, exponentially decaying as it does so, and turning its energy into heat. This part of the EM field penetrating the conductor (herein called “loss field”) induces an electric current within the conductor (herein called “loss current”). The density of this “loss current” inside the conductor is proportional to the strength of the “loss field”, being maximal near the conductor surface and decaying toward the interior of the conductor. This phenomenon is often called ‘skin effect’. The depth at which the wave of the “loss field” is attenuated by a factor of 1/e in the interior of the conductor is called “skin depth”. The propagation speed of the “loss field” and “skin depth” depend on the frequency of the EM wave and electromagnetic properties of the conductor, which is a direct outcome of Maxwell's equations. The higher the frequency of the signal, the less the skin depth and wave propagation speed are. The propagation speed of the electromagnetic (EM) wave inside a conductor is much slower than in a good dielectric or vacuum.

Suppose we apply a sinusoidal voltage signal to the conductor for a substantial time, so that both external EM field surrounding the conductor and the “loss field” inside the conductor achieve “steady state”. In this case there is no signal shape distortion at the load end of the conductor. Now suppose the applied signal is abruptly cancelled. The external EM field in a surrounding dielectric also cancels very quickly, as its propagation speed is high. The “loss field” inside the conductor decays for some time after signal cancellation due to its much slower propagation speed, so does the “loss current” induced by the “loss field”, therefore representing some “energy storage” or conductor “memory”. Moreover, the EM wave of the “loss field” and “loss current” experience phase shift inside the conductor. It can be easily shown that the phase of the wave of the “loss field” at the skin depth is changed by 1 radian—a far from negligible figure. Thus, a small portion of applied signal (external EM wave) and induced electric current are “memorized” and delayed inside the conductor. According to experiments and measurements, this conductor “memory” is capacitive in nature. This “memory” produces a signal shape and phase distortion in signal transmission lines. Despite this distortion is relatively small, especially at low frequencies, it may be of a significance for higher frequencies and for complex multi-frequency or impulse signals or where a very high signal transmission accuracy is required, e.g. in high-speed data transmission lines, medical systems, high quality audio/video systems, etc.

Known techniques attempt to reduce skin effect in the electric wires in order to maintain signal integrity with minimal electrical losses and distortions. The existing art includes specially geometric shaped conductors with increased surface area, including cables with arrayed solid and tinsel wire conductors, multi-layer conductors with different conductivity of layers, which stimulates the current to flow through the layers with higher conductivity, use of paramagnetic materials in the conductors for the similar purpose, etc. Other prior art methods include timing de-skewing means comprising storage for recording and storing information on skew and adjustment for generating and applying a correction. These methods are utilized to control the skin effect itself or results of the skin effect. The problem with these methods is that due to complex dependency of the “loss current” upon the signal frequency, conductor geometry, line characteristic impedance, signal source and load impedances, it is very difficult to effectively manage the skin effect uniformly across a wide frequency range.

U.S. Pat. No. 6,486,750 issued Nov. 26, 2002 to Disch discloses an electrical signal phase compensator having at least two conductors and a ground wire. U.S. Pat. No. 6,476,330 issued Nov. 5, 2002 to Otsuka et al. discloses a wiring substrate having a signal wiring suitable for transmitting high frequency. None of the aforementioned patents utilize a non-terminated compensating conductor as will be described herein.

It is well known in the art of signal transmission lines that in a non-terminated conductor, an electromagnetic wave is fully reflected from conductor's open (unconnected/non-terminated) end. As a result, a standing wave is formed, with the electric field wave (voltage) being reflected with the same sign and the magnetic field wave (current) being reflected with inverted sign. Though the electric current in a non-terminated conductor is effectively cancelled at its open end due to sign inversion, it still exists at a distance from its open end as a difference between direct and reflected current. The value of the current in an non-terminated conductor at a distance from its open end depends upon the strength and frequency of EM wave and the distance from the conductor's open end, and is proportional to sin(·*z/lambda), where z is the distance from conductor's open end, and lambda is the wavelength.

It has been determined by experiments and calculations that the current, induced in an non-terminated conductor at a distance from its open end has properties similar to the “loss current” in the terminated conductor, but has an opposite sign, as the current wave is reflected from non-terminated conductor's open end with sign inversion. Therefore, if we connect the terminated conductor to the non-terminated conductor, the electric current, induced in the non-terminated conductor, will compensate the “loss current” in the terminated conductor.

In the present invention a totally different and more effective approach is implemented versus prior art to directly compensate the signal transmission errors caused by skin effect, rather than attempt to manage the skin effect itself. Particularly, the electric “loss current” induced by the “loss field” in the main electric conductor(s) (the conductors that transfer electric current from the signal source to the load) is compensated by the similar current (“compensating current”) with opposite polarity induced in the additional non-terminated “compensating” conductor(s), one end of which is connected to the main electric conductor(s), and the other end is unconnected. Further details are described below.

### SUMMARY OF THE INVENTION

The primary aspect of the present invention is to provide a specially constructed ‘electric wire’, or compensating conductive circuit, capable of reducing the skin effect problems associated with signal transmission.

Another aspect of the present invention is to provide a compensating conductive circuit having one or more main electric conductors carrying current from a source to a load and having one or more non-terminated compensating conductors (non-terminated compensating electric conductors), each having one end connected to the main electric conductor(s) and another end non-terminated, or open.

Another aspect of the present invention is to provide for a plurality of configurations of both the main electric conductor and the non-terminated compensating conductor.

Still another aspect of the present invention is to provide for compensation of the electric ‘loss current’ induced by the ‘loss field’ in the main conductor(s) by a similar current with opposite polarity induced in the non-terminated, or open conductor(s).

Another aspect of the present invention is to provide a more effective signal distortion reduction having much less frequency dependence over a wide frequency range.

Other aspects of this invention will appear from the following description and appended claims, reference being made to the accompanying drawings forming a part of this specification wherein like reference characters designate corresponding parts in the several views.

The subject of the present invention, based on the background described above, is the compensating conductive circuit, comprising of at least one main electric conductor(s), that carries electric current from the signal source to the load, and additional non-terminated compensating conductor(s), one end of which is connected to the main electric conductor in order to compensate the “loss current” in the main conductor(s). In the invention herein, the word conductor refers to any material capable of carrying electrical conductance_{[L1]}. Such materials include but are not limited to copper, silver, aluminum, alloys etc. The term insulation or dielectric refers to an appropriate material utilized for electrical insulation such as polyethylene, polypropylene, polyvinyl chloride, rubber, enamel, and other such materials including flame retardant additives. All conductors are assumed to be either uninsulated or properly insulated and insulation is not specifically detailed.

The effectiveness of the “loss current” compensation depends upon such factors as the properties of the conductors, particularly the material, shape, capacitance and inductance of the main and compensating conductors both between themselves and other objects in vicinity, signal source, load impedances and transmission line characteristic impedance. The optimal compensation for a particular transmission line can be achieved by selecting the geometric shape, preferably the length, and number of compensating conductor(s). For EM wave wavelengths longer than the length of the transmission line, practically full “loss current” compensation can be achieved. In practice the “loss current” compensation method described herein is much more effective for signal distortion reduction and much less frequency-dependent over a wide frequency range than the prior art methods of managing the skin effect.

For example, digital signal cables built according to the “loss current” compensation method provide sharper signal edges, reduced phase and timing errors. Audio interconnect cables that utilize the technology of this invention, demonstrate sound richness, naturalness and clarity unachievable with traditional cables. Video cables designed according to the described principle of the present invention provide crisper picture with richer colors and detail than traditional video cables. Digital data carrying cables will present much less signal skew at the receiver end.

The present invention consists of various embodiments, form factors and such as described in the following:
1. A compensating conductive circuit for transmission of an electrical signal, comprising: at least one main electric conductor, having purpose of carrying electric current between the signal source and the load, and at least one compensating electric conductor; one end of said at least one compensating electric conductor connected to at least one said main electric conductor, while the other end of said compensating electric conductor is non-terminated (unconnected).
2. A compensating conductive circuit according to 1 above, wherein the length and/or cross-sectional shape and/or cross-sectional area of said at least one compensating conductor are chosen to enable maximal compensation of the signal distortions caused by skin effect in said at least one main electric conductor.
3. A compensating conductive circuit according to 1 above, wherein said at least one main electric conductor and said at least one compensating conductor are made of the same electrically conductive materials.
4. A compensating conductive circuit according to 2 above, wherein said at least one main electric conductor and said at least one compensating conductor include an internal electrically conductive core surrounded by an electrically conductive plating material, wherein the said core and said plating material are formed of different electrically conductive materials.
5. A compensating conductive circuit according to 1 above, wherein said at least one main electric conductor and said at least one compensating conductor are made of different electrically conductive materials.
6. A compensating conductive circuit according to 1 above, wherein said at least one main electric conductor and said at least one compensating conductor have circular cross-sectional shape.
7. A compensating conductive circuit according to 1 above, wherein said at least one main electric conductor and said at least one compensating conductor have at least substantially flat or tinsel shaped cross-sectional shape (tinsel type wire).
8. A compensating conductive circuit according to 1 above, wherein said at least one main electric conductor and said at least one compensating conductor have oval cross-sectional shape.
9. A compensating conductive circuit according to 1 above, wherein said at least one main electric conductor and said at least one compensating conductor have rectangular cross-sectional shape.
10. A compensating conductive circuit according to 1 above, wherein said at least one main electric conductor and said at least one compensating conductor are laid out in an arbitrary way in the space with respect to each other.
11. A compensating conductive circuit according to 1 above, wherein said at least one main electric conductor and said at least one compensating conductor are at least substantially parallel to each other.
12. A compensating conductive circuit according to 1 above, wherein said at least one main electric conductor and said at least one compensating conductor are at least substantially wound around one another.
13. A compensating conductive circuit according to 1 above, wherein said at least one main electric conductor and/or said at least one compensating conductor are at least substantially wound around a dielectric core.
14. The compensating conductive circuit according to 1 above, further comprising: at least one insulating layer formed between said at least one main electric conductor and said at least one compensating conductor.
15. The compensating conductive circuit according to 1 above, further comprising: at least one insulating layer around said at least one main electric conductor and/or around said at least one compensating conductor.
16. An electrical signal transmission system comprising the at least one electric wire of 1 above.
17. A circuit board (i.e. a printed circuit board or a wire board, and such), comprising: at least one electrical transmission lines embedded within the circuit board (CB), wherein at least one of said transmission lines includes at least one main electric conductor, connected to the signal source and to the load, and at least one compensating conductor; one end of said at least one compensating conductor is connected to said at least one main electric conductor, while the other end of said at least one compensating conductor is non-terminated (unconnected).
18. The transmission lines of 16 above wherein the main electrical conductor(s) is insulated from the compensating non-terminated conductor(s) by an insulating dielectric.
19. An electric cable comprising: a plurality of electric wires for transmission of electric current or signal, wherein at least one of said compensating electric circuit is the compensating conductive circuit according to 1 above.
20. The electric cable of 17 above wherein the electric wires have non-terminated compensating conductors connected at one end of the electric wires.
21. The main electric conductor(s) and the compensating non-terminated conductor(s) of 1, 16, 18 above can have a plurality of intermixed form factors including but not limited to tinsel wire, solid round or oval conductors, bundles with a plurality of conductors and so forth.
22. The form factors as per 19 above each having insulation or separated by a dielectric form factor.
23. The compensating conductive circuit of 1 above wherein the electric “loss current” induced by the “loss field” in the main electric conductor(s) is compensated by the similar current (“compensating current”) with opposite polarity induced in the additional non-terminated compensating conductor(s), one end of which is connected to the main electric conductor(s), and the other end is non-terminated (unconnected).

### BRIEF DESCRIPTION OF THE DRAWINGS

FIG. 1a is a simple layout of the compensating conductive circuit showing one main electric conductor terminated at a load impedance and one non-terminated compensating conductor connected to the one main electric conductor at the source.

FIG. 1b is a simple layout of the compensating conductive circuit showing two main electric conductors terminated at a load impedance and two non-terminated compensating conductors connected to the two main electric conductors at the source.

FIG. 1c is a simple layout of the compensating conductive circuit showing one main electric conductor terminated at a load impedance and two non-terminated compensating conductors one connected to the main electric conductor at the source and the other connected to the main electric conductor at about the half way point to the load.

FIG. 1d is a simple layout of the compensating conductive circuit showing one main electric conductor terminated at a load impedance and two non-terminated compensating conductors one connected to the main electric conductor at the source and the other connected to the main electric conductor at the load impedance, each about half the length of the main electric conductor.

FIG. 2a is a simple layout of the compensating conductive circuit showing one main electric conductor and one non-terminated compensating conductor laid out in an arbitrary way in the space with respect to one another.

FIG. 2b is a simple layout of the compensating conductive circuit showing one main electric conductor and one non-terminated compensating conductor laid out essentially parallel to one another.

FIG. 2c is a simple layout of the compensating conductive circuit showing one main electric conductor with one non-terminated compensating conductor essentially wound around the main electric conductor.

FIG. 2d is a simple layout of the compensating conductive circuit showing one main electric conductor wound around one non-terminated compensating conductor.

FIG. 2e is a simple layout of the compensating conductive circuit showing one main electric conductor wound around one non-terminated compensating conductor having a dielectric core.

FIGS. 3a, 3b, 3c, 3d are cross sectional views of various prior art conductor configurations.

FIGS. 4a, 4b, 4c are cross sectional views of various prior art conductor configurations containing multiple conducting layers.

FIG. 5a is a basic schematic of the compensating conductive circuit of the present invention showing the transmission and return paths from a source to a load both having non-terminated compensating conductors.

FIG. 5b is similar to FIG. 5a showing basic schematic of the compensating conductive circuit of the present invention showing the transmission and return paths from a source to a load but having only one non-terminated compensating conductor.

FIG. 6a is a basic schematic of the compensating conductive circuit of the present invention showing the non-terminated compensating conductors essentially wrapped around the main transmission and return conductors but connected at opposite source points to the main conductor to which it is wrapped.

FIG. 6b is similar to FIG. 6a but with non-terminated compensating conductors essentially connected to the same main conductor source point to which it is wrapped.

FIGS. 7a, 7b, 7c are simple layouts of various compensating conductive circuits on a Printed Circuit Board.

FIGS. 8a, 8b, 8c are cross sectional layouts of compensating conductive circuits on a Printed Circuit Board.

FIG. 9a is a cross sectional view of a prior art co-axial cable.

FIG. 9b is a basic schematic of a co-axial cable compensating conductive circuit of the present invention showing the transmission and return paths from a source to a load having a non-terminated compensating conductor.

The above brief description, as well as the features, aspects and advantages of the present invention will become better understood with regard to the following description and detailed drawings.

Before explaining the disclosed embodiment of the present invention in detail, it is to be understood that the invention is not limited in its application to the details of the particular arrangement shown, since the invention is capable of other embodiments. Also, the terminology used herein is for the purpose of description and not of limitation.

### DETAILED DESCRIPTION OF THE DRAWINGS

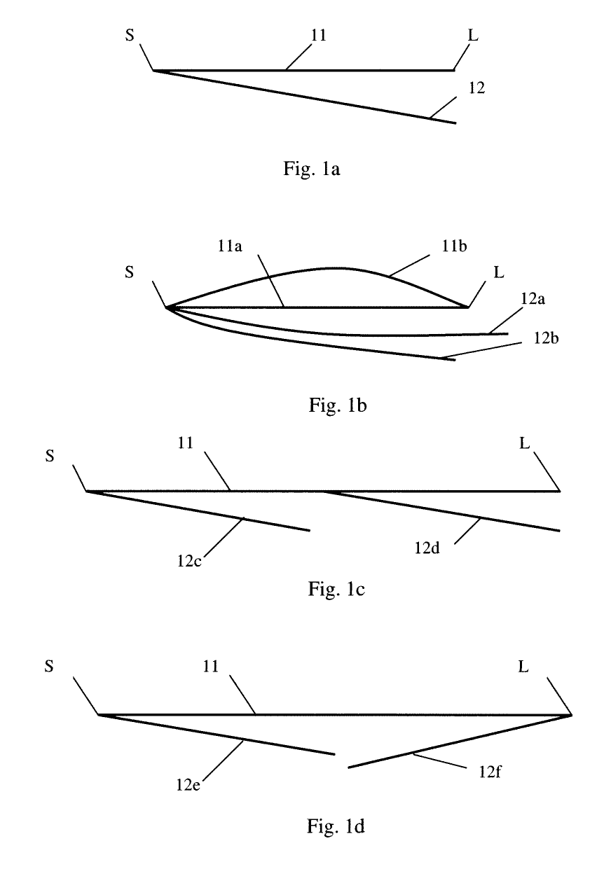

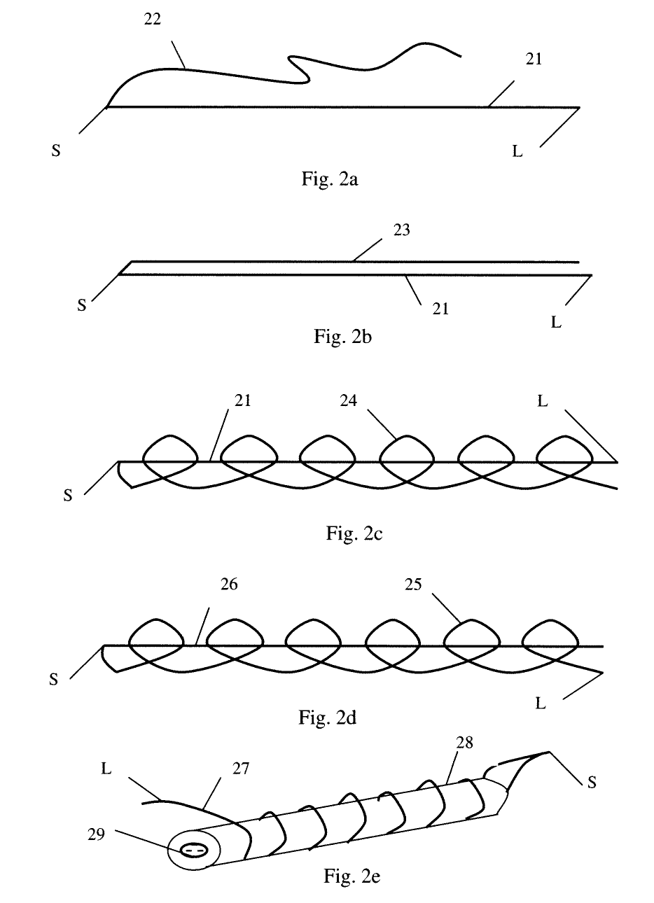

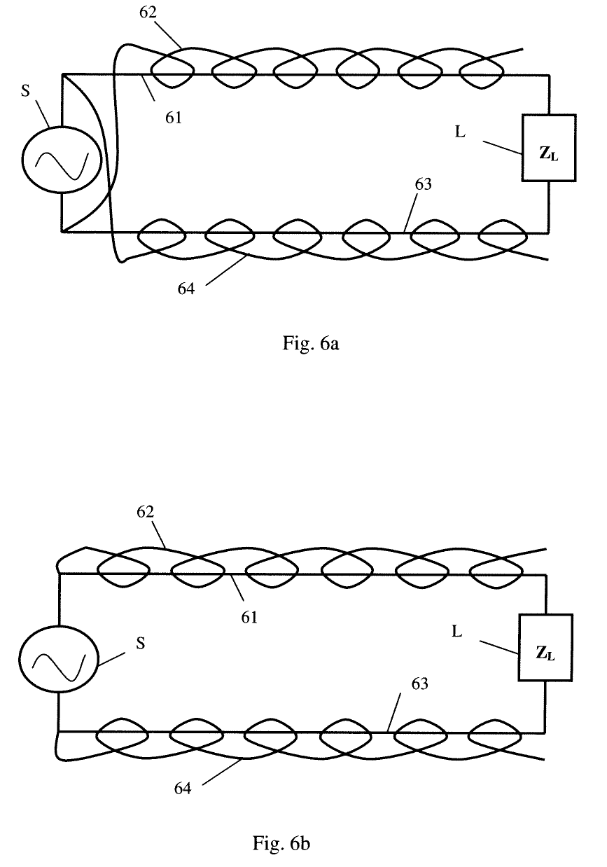

The drawings that follow are constructions of the compensating conductive circuit of the present invention and are presented by way of example and not of limitation. Several variations may be made without departing from the scope of the invention. In the drawings that follow the symbol ‘L’ represents a load impedance Z_{L} whereas the symbol ‘S’ represents a signal source. Typically there will be a signal path from the source to the load impedance and a return path from the load impedance to the source as shown in FIGS. 5a, 5b, 6a, 6b. Construction layouts shown in FIGS. 1a thru 1d, and FIGS. 2a thru 2e do not show both paths and are meant to show construction embodiments only. All conductor insulation is not specifically shown but is assumed to be present as required.

FIG. 1a is a simple layout of the compensating conductive circuit of the present invention showing one attached main electric conductor 11 originating at signal source S and terminated at a load impedance L and one non-terminated compensating conductor 12 connected to main electric conductor 11 at the signal source S and left non-terminated, or open at its other end.

FIG. 1b is a simple layout of the compensating conductive circuit of the present invention showing two main electric conductors 11a, 11b which are both terminated at a load impedance L and two non-terminated compensating conductors 12a, 12b which are connected to the two main electric conductors 11a, 11b at the source S and non-terminated at their other end.

FIG. 1c is a simple layout of the compensating conductive circuit showing one main electric conductor 11 terminated at load impedance L and two non-terminated compensating conductors 12c, 12d with one non-terminated compensating conductor 12c connected to the main electric conductor at the source S and the other non-terminated compensating conductor 12d connected to the main electric conductor 11 at about the half way point to load impedance L.

FIG. 1d is a simple layout of the compensating conductive circuit showing one main electric conductor 11 terminated at load impedance L and two non-terminated compensating conductors 12e, 12f one non-terminated compensating conductor 12e connected to main electric conductor 11 at the source and the other non-terminated compensating conductor 12d connected to the main electric conductor at load impedance L, each about half the length of the main electric conductor.

FIG. 2a is a simple layout of the compensating conductive circuit showing one main electric conductor 21 and one non-terminated compensating conductor 22 laid out in an arbitrary way in the space with respect to one another. Main electric conductor 21 runs from source S to load impedance L whereas non-terminated compensating conductor 22 is connected to main electric conductor 21 at source S only and left non-terminated at its other end.

FIG. 2b is a simple layout of the compensating conductive circuit showing one main electric conductor 21 and one non-terminated compensating conductor 23 laid out essentially parallel to one another. Main electric conductor 21 runs from source S to load impedance L whereas non-terminated compensating conductor 23 is connected to main electric conductor 21 at source S only and left non-terminated at its other end.

FIG. 2c is a simple layout of the compensating conductive circuit showing one main electric conductor 21 with one non-terminated compensating conductor 24 essentially wound around the main electric conductor 21. Main electric conductor 21 runs from source S to load impedance L whereas non-terminated compensating conductor 23 is connected to main electric conductor 21 at source S only and left non-terminated at its other end.

FIG. 2d is a simple layout of the compensating conductive circuit showing one main electric conductor 25 wound around one non-terminated compensating conductor 26. Main electric conductor 25 runs from source S to load impedance L whereas non-terminated compensating conductor 26 is connected to main electric conductor 25 at source S only and left non-terminated at its other end.

FIG. 2e is a simple layout of the compensating conductive circuit showing one main electric conductor 27 wound around one non-terminated compensating conductor 28 having a dielectric core 29. Main electric conductor 27 runs from source S to load impedance L whereas non-terminated compensating conductor 28 is connected to main electric conductor 27 at source S only and left non-terminated at its other end.

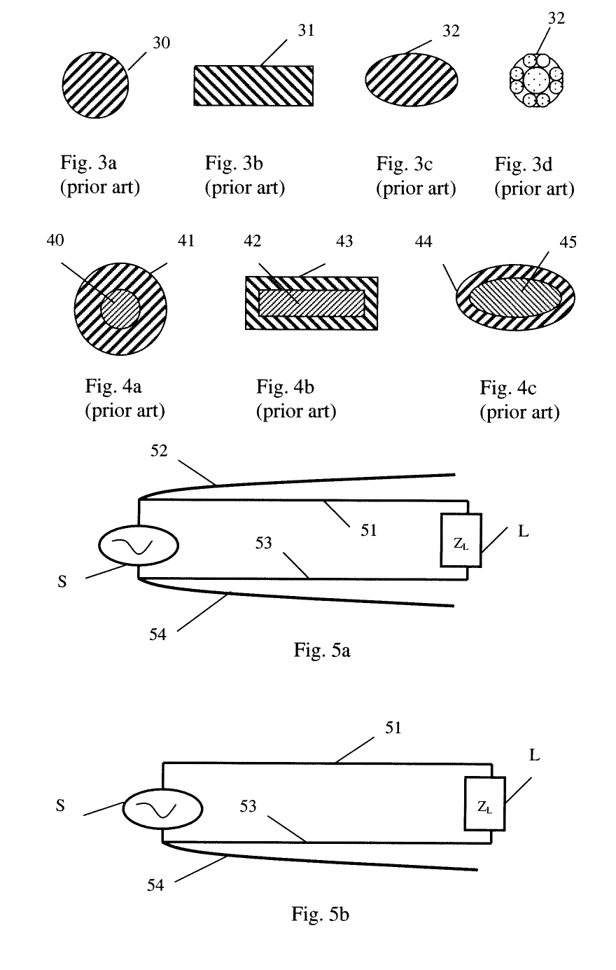

FIGS. 3a, 3b, 3c, 3d are cross sectional views of various prior art conductor configurations. FIG. 3a represents a cross-sectional view of a round solid conductor 30 whereas FIG. 3c represents an oval shaped conductor 32. These conductors can be of varying gauges. FIG. 3b represents a rectangular shaped conductor 31. Flat, thin conductors are often referred to as tinsel conductors. Flat conductors such as tinsel optimize high frequency performance. FIG. 3d represents a multi-stranded conductor having a larger diameter inner strand surrounded by a plurality of smaller core conductor strands. Although not shown, it should be noted that the construction of multi-stranded conductors can consist of a variety of geometric shapes, sized, metals, coatings, alloys, metallic coatings, insulations, and the like as exist in the art.

FIGS. 4a, 4b, 4c are cross sectional views of various conductor configurations containing multiple conductive layers. FIG. 4a represents a cross-sectional view of a round solid conductor 40 having plated layer 41 whereas FIG. 4c represents an oval shaped conductor 45 having plated layer 44. These conductors can be of varying gauges. FIG. 4b represents a rectangular shaped conductor 42 having plated layer 43. Flat conductors optimize high frequency performance. One variation of flat, thin conductors are often referred to as tinsel conductors. Conductors having multiple conducting layers, i.e. copper with silver plating, aluminum with nickel plating, etc. enhance high frequency transmission. There are also available conductor products with dielectric cores within the conductors to further enhance frequency performance.

FIG. 5a is a basic schematic of the compensating conductive circuit of the present invention showing the main transmission conductor 53 from source S to impedance load L with non-terminated compensating conductor 54 attached at source S. Return conductor 51 from a impedance load L to source S has non-terminated compensating conductor 52 attached to source S. Non-terminated compensating conductors 52 or 54 are shown essentially parallel to each main conductor but could also be laid out in an arbitrary manner.

FIG. 5b is similar to FIG. 5a showing basic schematic of the compensating conductive circuit of the present invention showing the main transmission conductor 53 from source S to impedance load L with non-terminated compensating conductor 54 attached at source S. Return conductor 51 from a impedance load L to source S is shown without a non-terminated compensating conductor. It should be noted that non-terminated compensating conductor 54 could as well be attached only to the return path at source S, or could be attached only at the load impedance L at the transmission or return path end. Non-terminated compensating conductors 54 is shown essentially parallel to main conductor 53 but could also be laid out in an arbitrary manner.

FIG. 6a is a basic schematic of the compensating conductive circuit of the present invention showing the non-terminated compensating conductors 62, 64 essentially wrapped around the main transmission conductor 63 and return conductor 61 respectively. The non-terminated compensating conductors are connected at opposite source points to the main conductor to which each is wrapped.

FIG. 6b is similar to FIG. 6a but with non-terminated compensating conductors 62, 64 connected to the same main conductor source point to which it is wrapped. That is compensating conductor 64 is wrapped about and is connected to main transmission conductor 63 at a common source point and compensating conductor 62 is wrapped about and is connected to main return path conductor 61 at a common source point.

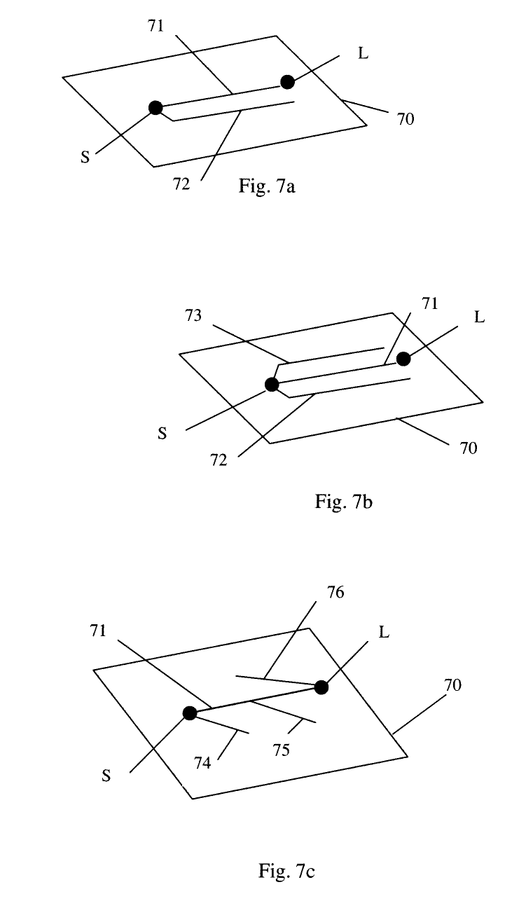

FIGS. 7a, 7b, 7c are simple layouts of various compensating conductive circuits on a Printed Circuit Board.

FIG. 7a is a simple layout of the compensating conductive circuit on a PC Board 70 showing main electric conductor 71 terminated at a load impedance L and one non-terminated compensating conductor 72 connected to the one main electric conductor at the source S.

FIG. 7b is a simple layout of the compensating conductive circuit on PC Board 70 showing main electric conductor 71 terminated at a load impedance L and two non-terminated compensating conductors 72, 73 connected to the main electric conductor 71 at the source S.

FIG. 7c is a simple layout of the compensating conductive circuit on PC Board 70 showing one main electric conductor 71 terminated at a load impedance L and three non-terminated compensating conductors 74, 75, 76 one 74 connected to the main electric conductor 71 at the source S another 75 connected to the main electric conductor 71 at about the half way point to the load L, and a third 76 connected to the main electric conductor 71 at load L.

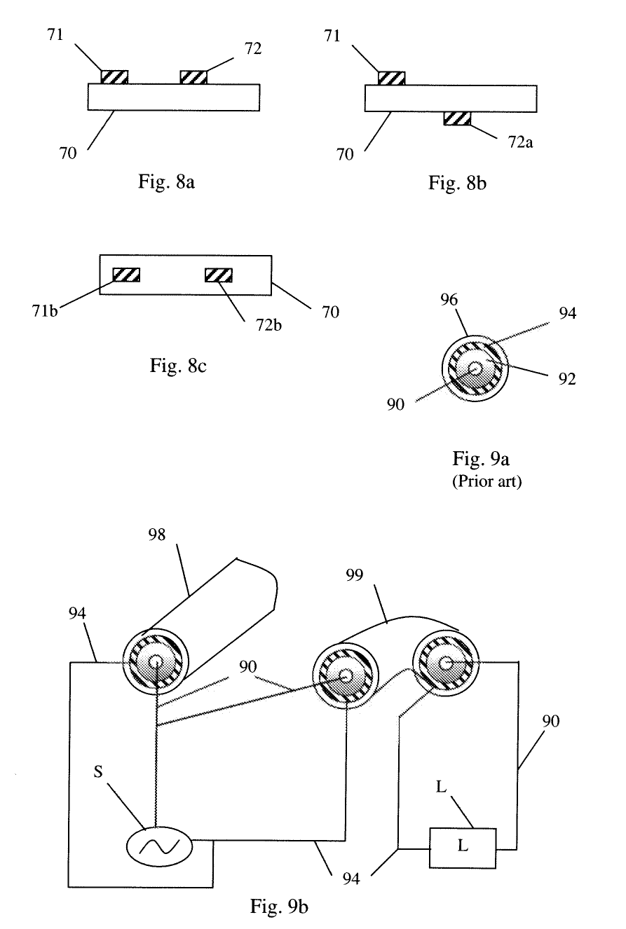

FIGS. 8a, 8b, 8c are cross sectional layouts of compensating conductive circuits on PCB 70. Prior art circuit board construction is used. In FIG. 8a main electrical conductor 71 and non-terminated compensating conductor 72 are shown on a PCB surface. In FIG. 8b main electrical conductor 71 is shown on the top surface of PCB 70 while non-terminated compensating conductor 72a is shown on the bottom PCB surface. In FIG. 8c main electrical conductor 71b and non-terminated compensating conductor 72b are shown on internal layers of a multi-layered PCB.

FIG. 9a is a cross sectional view of a prior art co-axial cable showing internal main conductor 90, main conductor insulation 92, outer conductor 94 and external insulation 96. Prior art co-axial cable construction is used.

FIG. 9b is a basic schematic of a co-axial cable compensating conductive circuit showing the transmission and return paths from a source S to a load L and having a non-terminated compensating conductor 98. It is similar to FIG. 5b for standard cable. One end of source S is common connected to each internal main conductor 90 of both non-terminated compensating conductor 98 and main conductor 99. The return path from load L is outer conductor 94 of main conductor 99 which connects to source S return and also connects to non-terminated compensating conductor 98 at its outer conductor 94.

The above descriptions include various geometries, constructions, gauges and the like related to implementation in cables, circuit boards, and other forms of transmission lines having one or more conductors. As described herein, all main conductors and compensating conductors can be of any shape, length, material, single stranded, multi-stranded, etc. They can be insulated, non-insulated wound about one another etc. All constructions and variations can be made without departing from the scope of the invention.

The “loss current” compensation method of the present invention is much more effective for signal distortion reduction and much less frequency-dependent over a wide frequency range than the prior art methods. It can provide sharper signal edges, reduced phase and timing errors.

Although the present invention has been described with reference to preferred embodiments, numerous modifications and variations can be made and still the result will come within the scope of the invention. No limitation with respect to the specific embodiments disclosed herein is intended or should be inferred. Each apparatus embodiment described herein has numerous equivalents.

1. A compensating conductive circuit comprising:
an electric conductor having a length LH connected from a signal source S to a load L;
a first non-terminated compensating electric conductor connected to the source S; and
a second non-terminated compensating electric conductor connected to the electric conductor at about a half-way point between the soruce S and the load L.

2. The apparatus of claim 1 further comprising a second non-terminated compensating electric conductor connected to the electric conductor at about a half way point between S and L.

3. The apparatus of claim 1 further comprising a second non-terminated compensating electric conductor connected to L, and wherein each of the first and second non-terminated compensating electric conductors have a length of about one half LH.

4. The apparatus of claim 1, wherein the first non-terminated compensating electric conductor has a shape about straight and laid out along a direction toward said load L and having a length about the same as said length LH.

5. The apparatus of claim 1, wherein the first non-terminated compensating electric conductor is laid out in an arbitrary way with respect to the electric conductor, and has a length about the same as said length LH.

6. The apparatus of claim 1, wherein the first non-terminated compensating electric conductor is laid out about parallel to the electric conductor, and has a length about the same as said length LH.

7. The apparatus of claim 1, wherein the first non-terminated compensating electric conductor is wound around the electric conductor, and has a length greater than LH.

8. The apparatus of claim 1, wherein the electric conductor is wound around the first non-terminated compensating electric conductor, and LH is longer than a length of the non-terminated compensating electric conductor.

9. The apparatus of claim 8, wherein the non-terminated compensating electric conductor further comprises a dielectric core.

10. The apparatus of claim 1 further comprising a second electric conductor connected from L to S and a second non-terminated compensating electric conductor connected to S.

11. A compensating conductive circuit comprising:
a first and a second electric conductor connected between a signal source S and a load L; and
a first non-terminated compensating electric conductor connected to L.

12. The apparatus of claim 10, wherein the first non-terminated compensating electric conductor is wrapped around the second electric conductor, and the second non-terminated compensating electric conductor is wrapped around the first electric conductor.

13. The apparatus of claim 10, wherein the first and second non-terminated compensating electric conductors are wrapped around their respective first and second electric conductors.

14. The apparatus of claim 1, wherein the electric conductor and the first non-terminated compensating electric conductor are part of a printed circuit board.

15. The apparatus of claim 14, wherein the electric conductor and the non-terminated compensating electric conductor are located on an outside surface of the printed circuit board.

16. The apparatus of claim 14, wherein the electric conductor and the non-terminated compensating electric conductor are located on an internal layer of the printed circuit board.

17. A compensating electric circuit comprising:
a signal source S and a load L;
a first and a second coaxial cable each having a central conductor with a surrounding insulator and an outer conductor with external insulation;
wherein the first coaxial cable is a non-terminated compensating electric conductor;
wherein one end of S is common connected to a respective end of each of the central conductors of the first and second coaxial cables;
wherein the opposite end of S is common connected to the outer conductors of both the first and the second coaxial cable at their same respective end; and
wherein L is connected between the central conductor and the outer conductor of an opposite end of the second coaxial cable.

18. The apparatus of claim 17, wherein a primary circuit is completed by connecting L across the central conductor and the outer conductor at one end of the second coaxial cable and connecting S across the central conductor and the outer conductor at the opposite end of the second coaxial cable.

19. The apparatus of claim 17, wherein one end of the first coaxial cable forms a non-terminated compensating electric conductor having its central conductor and its outer conductor connected to respective sides of S at one end and having its opposite end non-terminated.
